(19) United States
(12) Patent Application Publication
(10) Pub. No.: US 2026/0139363 A1
(43) Pub. Date: May 21, 2026

(54) METHOD FOR MANUFACTURING AN EQUIAXED CRYSTAL TARGET

(71) Applicant: METAL INDUSTRIES RESEARCH & DEVELOPMENT CENTRE, Kaohsiung (TW)

(72) Inventor: Shun-Yu SHAO, Kaohsiung (TW)

(21) Appl. No.: 19/249,411

(22) Filed: Jun. 25, 2025

(30) Foreign Application Priority Data
Nov. 21, 2024 (TW) 113144971

(51) Int. Cl. C23C 14/34; C22F 1/08

(52) U.S. Cl. CPC C23C 14/3414; C22F 1/08

(57) ABSTRACT

A method for manufacturing an equiaxed crystal target includes steps. A bar-shaped metal material is formed to a forged material by using a radial forging process. The forged material is formed to a first plate material by using a rolling process and a plate forging process, wherein the rolling process is to roll the forged material along an axial direction thereof. An equal channel angular extrusion mold is used to reciprocally perform an equal channel angular extrusion process on the first plate material to obtain a second plate material, wherein a cumulative average equivalent strain of the second plate material is greater than 10, and a feeding direction of the first plate material into the equal channel angular extrusion mold is the same as the axial direction of the forged material. A recrystallization annealing/heat treatment process is performed on the second plate material to obtain an equiaxed crystal target.

This application claims the benefit of Taiwan Patent Application No. 113144971, filed on Nov. 21, 2024, which is hereby incorporated by reference for all purposes as if fully set forth herein.

### BACKGROUND

### Technical Field

The present disclosure relates to a method for manufacturing a target, and in particular, to a method for manufacturing an equiaxed crystal target.

### Related Art

As the demand for portable electronic products is increased, semiconductor devices are also moving towards miniaturization, and the quality of thin films in semiconductor devices is also improving accordingly.

Sputtering is a process in which plasma strikes a target material to cause the target to release atoms due to the impact energy and accumulate on the substrate to form a thin film. The thin film formed by the sputtering process has high adhesion and high uniformity and is widely used in semiconductor processes. The power value, the sputtering rate and other parameters used in the sputtering process are not only related to the quality of the thin film formed in the sputtering process, but also the quality of the target material is an important factor. Generally speaking, the purity of the target used in the sputtering process of the semiconductor is required to be above 4 N (99.99%), and the grain size of the target must be less than 30 nm in order to form the thin film on the substrate that meets the requirements for electrical performance and film thickness uniformity.

The conventional target preparation method uses a multi-directional free forging method to plastically deform an aluminium ingot, and then cold-rolls the aluminium ingot at 0 to 5° C. to achieve grain refinement. However, there are problems such as complex process, high production cost, and the inability to achieve uniform distribution of grain refinement size below 100 μm.

Patent document (CN 109518140 A) discloses a method for manufacturing an ultra-high purity, equiaxed fine-grained aluminium target, which is characterized by comprising the following steps of: (1) remelting: placing a high purity aluminium ingot in a vacuum furnace for remelting, and obtaining a high purity aluminium liquid after complete melting; (2) recasting: pouring the high purity aluminium liquid into a casting mold for recasting, and electromagnetically stirring the high purity aluminium liquid during the cooling process to obtain a newly cast high purity aluminium ingot after recasting; (3) annealing: keeping the newly cast high purity aluminium ingot at 200-400° C. and then cooling it to room temperature; (4) forging: forging the newly cast high purity aluminium ingot after annealing; (5) rolling: rolling the newly cast high purity aluminium ingot after forging; (6) performing a heat preservation and cooling treatment on the newly cast high purity aluminium ingot after rolling to obtain an ultra-high purity equiaxed aluminium with a grain size of less than 100 μm. However, the equiaxed crystal target in the patent document is for pure aluminium material, and steps of the method for manufacturing the equiaxed crystal target are relatively complicated.

Therefore, a method for manufacturing an equiaxed crystal target needs to be provided to resolve the forgoing problems.

### SUMMARY

An objective of the present disclosure is to provide a method for manufacturing an equiaxed crystal target, wherein the method can manufacture an equiaxed crystal target with a grain size not greater than 20 μm, and after processing, the equiaxed crystal target can be formed to an equiaxed crystal target for semiconductor sputtering process.

To achieve the foregoing objective, the present disclosure provides a method for manufacturing an equiaxed crystal target comprising the steps of: forming a bar-shaped metal material to a forged material by using a radial forging process; forming the forged material to a first plate material by using a rolling process and a plate forging process, wherein the rolling process is to roll the forged material along an axial direction thereof; using an equal channel angular extrusion mold to reciprocally perform an equal channel angular extrusion process on the first plate material to obtain a second plate material, wherein a cumulative average equivalent strain of the second plate material is greater than 10, and a feeding direction of the first plate material into the equal channel angular extrusion mold is the same as the axial direction of the forged material; and performing a recrystallization annealing and heat treatment process on the second plate material to obtain an equiaxed crystal target.

In some embodiments, the recrystallization annealing and heat treatment process is performed on the second plate material to obtain the equiaxed crystal target material by using an induction heat treatment device, wherein a grain size of the equiaxed crystal target is not greater than 20 μm.

In some embodiments, a heat treatment temperature of the recrystallization annealing and heat treatment process is below the recrystallization temperature of the bar-shaped metal material.

In some embodiments, when the bar-shaped metal material is pure copper, the heat treatment temperature of the recrystallization annealing and heat treatment process is between 300 and 400° C., and the heat treatment time is between 30 and 60 minutes.

In some embodiments, the grain size difference between the grains of the equiaxed crystal target is no more than one grain size number.

In some embodiments, when the number of extrusions of the equal channel angular extrusion process is not less than 4 times, a grain size of the equiaxed crystal target is not greater than 5 μm.

In some embodiments, when the equal channel angular extrusion process is performed, the first plate material and the equal channel angular extrusion mold are lubricated at the same time.

In some embodiments, after the radial forging process, the cumulative center equivalent strain of a core portion of the forged material is greater than 2, and after the rolling process and the plate forging process, the cumulative center equivalent strain of a core material of the first plate material is greater than 5.

In some embodiments, the bar-shaped metal material is made of pure copper or copper-manganese.

In some embodiments, after the recrystallization annealing and heat treatment process, a mechanical processing process is performed on the equiaxed crystal target.

The above-mentioned steps of the method manufacturing for the equiaxed crystal target in the present disclosure can obtain an equiaxed crystal target with a grain size not greater than 20 μm for use in the semiconductor industry.

### BRIEF DESCRIPTION OF THE DRAWINGS

FIG. 1 is a flow chart of a method for manufacturing an equiaxed crystal target of the present disclosure.

FIG. 2 shows a schematic three-dimensional view of a radial forging process of a method for manufacturing an equiaxed crystal target of the present disclosure.

FIG. 3 shows a schematic partially three-dimensional view of an equal channel angular extrusion process of a method for manufacturing an equiaxed crystal target of the present disclosure.

### DETAILED DESCRIPTION

The embodiments of the present disclosure are described in detail with reference to the drawings as follows. The drawings are mainly simplified schematic diagrams, which only illustrate the basic structure of the present disclosure in a schematic manner. Therefore, only components related to the present disclosure are marked in the drawings, and the components shown are not drawn in terms of number, shape, size ratio, etc. during implementation. The specifications and dimensions during actual implementation are actually a selective design, and the component layout may be more complicated.

The following descriptions of the embodiments refer to the attached drawings to illustrate specific embodiments in which the present disclosure may be implemented. Directional terms mentioned in the present disclosure, such as “upper”, “lower”, “front”, “rear”, etc., are only used to refer to the directions of the accompanying drawings. Therefore, the directional terms used are for explaining and understanding the present disclosure, but not to limit the present disclosure. In addition, in the specification, unless explicitly described to the contrary, the word “comprising” will be understood to mean the inclusion of stated elements but not the exclusion of any other elements.

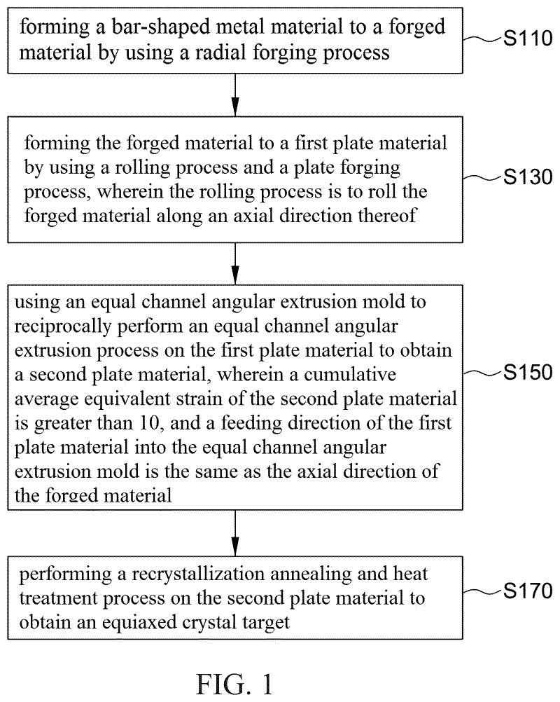

Referring to FIG. 1, which is a flow chart of a method for manufacturing an equiaxed crystal target of the present disclosure, the method includes the following steps:

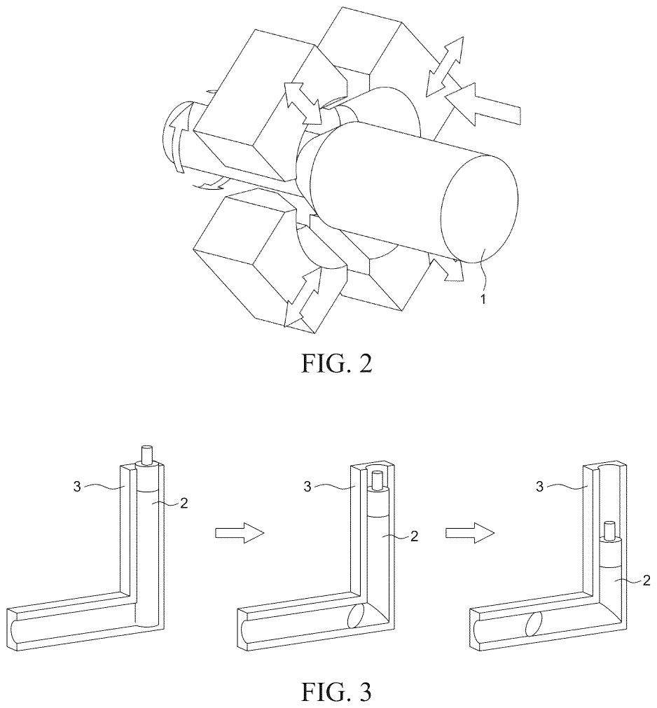

A bar-shaped metal material 1 is formed to a forged material by using a radial forging process (in step S110). In one embodiment, after the radial forging process, the cumulative central equivalent strain of a core portion of the forged material is greater than 2, so as to initially refine the grains of the bar-shaped metal material 1 and reduce the difference in grain size in the same direction. Preferably, the radial forging process can be performed at low temperature or room temperature, so that the degree of grain crushing of the bar-shaped metal material 1 is higher, thereby making the grain size of the bar-shaped metal material 1 smaller. Referring to FIG. 2, the radial forging process may be performed by using a cogging device, and the bar-shaped metal material 1 is formed to the forged material in four directions. The radial forging amount may be adjusted to produce the forged material of a predetermined size.

In one embodiment, the bar-shaped metal material 1 can be made of pure copper or copper-manganese, wherein the purity of the pure copper may be above 6 N (99.9999%).

The forged material is formed to a first plate material by using a rolling process and a plate forging process, wherein the rolling process is to roll the forged material along an axial direction thereof (in step S130). In one embodiment, after the rolling process and the plate forging process, the cumulative center equivalent strain of a core portion of the first plate material is greater than 5. The rolling process and the plate forging process can not only control the grain direction, but also enable the core portion of the first plate material to obtain a larger strain, thereby reducing the strain difference from the outer edge portion to the core portion of the first plate material. Preferably, the plate forging process can be performed at low temperature (for example, the temperature is not more than 200° C.) or room temperature to prevent the grains of the first plate material from growing and increasing in a high temperature environment, so as to maintain fine grains. After the rolling process, the forged material is preferably rolled to a thick plate with a width-to-thickness ratio of 4 to 8, and after the plate forging process, the forged material is then forged to a thin plate (i.e., the first plate material).

Referring to FIG. 3, an equal channel angular extrusion mold 3 is used to reciprocally perform an equal channel angular extrusion process on the first plate material 2 to apply a large angle shear strain to the first plate material 2 as a whole so that the grains are violently crushed to form fine sub-grains, thereby obtaining a second plate material, wherein a cumulative average equivalent strain of the second plate material is greater than 10 (in step S150). A feeding direction of the first plate material 2 into the equal channel angular extrusion mold 3 is the same as the axial direction of the forged material (i.e., the rolling direction of the rolling process). During the above equal channel angular extrusion process, the first plate material 2 is extruded, thereby passing through the corner of the equal channel angular extrusion mold 3 in a reciprocating way.

In one embodiment, when the equal channel angular extrusion process is performed, the first plate material 2 and the equal channel angular extrusion mold 3 can be lubricated (e.g., by material coating and lubricant) at the same time.

A recrystallization annealing and heat treatment process is performed on the second plate material to obtain an equiaxed crystal target (in step S170). After the recrystallization annealing and heat treatment process, a mechanical processing process is performed on the equiaxed crystal target. In one embodiment, the recrystallization annealing and heat treatment process can be performed on the second plate material by using an induction heat treatment device, so that the grain size of the obtained equiaxed crystal target can be not greater than 20 μm when the number of extrusions in the equal channel angular extrusion process is one time. And, the grain size difference between the grains of the equiaxed crystal target is no more than one grain size number wherein the grain size number can be obtained by measuring standards such as ASTM E112, ASTM E1382, IS 4748, etc.

It is worth mentioning that the induction heat treatment device is used to perform the recrystallization annealing and heat treatment process on the second plate material, and can heat the entire second plate material to the required temperature within a few seconds. Then, the second plate material is quickly quenched to achieve the effect of rapid heating and cooling, so as to obtain a relatively high degree of refinement of the grain size of the equiaxed crystal target.

In one embodiment, the heat treatment temperature of the recrystallization annealing and heat treatment process is below the recrystallization temperature of the bar-shaped metal material 1. When the bar-shaped metal material 1 is pure copper, the heat treatment temperature of the recrystallization annealing and heat treatment process is between 300 and 400° C., and the heat treatment time is between 30 and 60 minutes.

In another embodiment, when the number of extrusions of the equal channel angular extrusion process is not less than 4 times, the grain size of the equiaxed crystal target is not greater than 5 μm. The extrusion angle of the equal channel angular extrusion mold 3 can be between 30 and 90 degrees. It can be understood that before performing the aforementioned recrystallization annealing and heat treatment process, the method manufacturing for the equiaxed crystal target in the present disclosure does not perform an additional heat treatment process, so the equivalent strain inside the material can be accumulated. It helps to form equiaxed fine crystals after the recrystallization annealing and heat treatment process.

As described above, the above-mentioned steps of the method manufacturing for the equiaxed crystal target in the present disclosure can obtain an equiaxed crystal target with a grain size not greater than 20 μm for use in the semiconductor industry.

Based on the above, only the preferred implementations or embodiments of the technical means adopted by the present disclosure for resolving the problems are recorded, and are not intended to limit the scope of patent implementation of the present disclosure. To be specific, all equivalent changes and modifications made in accordance with the scope of the patent application of the present disclosure or made in accordance with the scope of the patent of the present disclosure fall within the scope of the patent of the present disclosure.

What is claimed is:

1. A method for manufacturing an equiaxed crystal target comprising the steps of:
forming a bar-shaped metal material to a forged material by using a radial forging process;
forming the forged material to a first plate material by using a rolling process and a plate forging process, wherein the rolling process is to roll the forged material along an axial direction thereof;
using an equal channel angular extrusion mold to reciprocally perform an equal channel angular extrusion process on the first plate material to obtain a second plate material, wherein a cumulative average equivalent strain of the second plate material is greater than 10, and a feeding direction of the first plate material into the equal channel angular extrusion mold is the same as the axial direction of the forged material; and
performing a recrystallization annealing and heat treatment process on the second plate material to obtain an equiaxed crystal target.

2. The method for manufacturing an equiaxed crystal target according to claim 1, wherein the recrystallization annealing and heat treatment process is performed on the second plate material to obtain the equiaxed crystal target material by using an induction heat treatment device, wherein a grain size of the equiaxed crystal target is not greater than 20 μm.

3. The method for manufacturing an equiaxed crystal target according to claim 2, wherein a heat treatment temperature of the recrystallization annealing and heat treatment process is below the recrystallization temperature of the bar-shaped metal material.

4. The method for manufacturing an equiaxed crystal target according to claim 3, wherein when the bar-shaped metal material is pure copper, the heat treatment temperature of the recrystallization annealing and heat treatment process is between 300° C. and 400° C., and the heat treatment time is between 30 minutes and 60 minutes.

5. The method for manufacturing an equiaxed crystal target according to claim 2, wherein the grain size difference between the grains of the equiaxed crystal target is no more than one grain size number.

6. The method for manufacturing an equiaxed crystal target according to claim 1, wherein when the number of extrusions of the equal channel angular extrusion process is not less than 4 times, a grain size of the equiaxed crystal target is not greater than 5 μm.

7. The method for manufacturing an equiaxed crystal target according to claim 1, wherein when the equal channel angular extrusion process is performed, the first plate material and the equal channel angular extrusion mold are lubricated at the same time.

8. The method for manufacturing an equiaxed crystal target according to claim 1, wherein after the radial forging process, the cumulative center equivalent strain of a core portion of the forged material is greater than 2, and after the rolling process and the plate forging process, the cumulative center equivalent strain of a core material of the first plate material is greater than 5.

9. The method for manufacturing an equiaxed crystal target according to claim 1, wherein the bar-shaped metal material is made of pure copper or copper-manganese.

10. The method for manufacturing an equiaxed crystal target according to claim 1, wherein after the recrystallization annealing and heat treatment process, a mechanical processing process is performed on the equiaxed crystal target.
